(19) United States
(12) Patent Application Publication
(10) Pub. No.: US 2025/0311109 A1
(43) Pub. Date: Oct. 2, 2025

(54) LAMINATE FOR ELECTRONIC DEVICES AND METHOD FOR PRODUCING SAME, AND ELECTRONIC DEVICE USING SAME

(71) Applicant: PANASONIC INTELLECTUAL PROPERTY MANAGEMENT CO., LTD., Osaka (JP)

(72) Inventors: Kyosuke MICHIGAMI, Tokushima (JP); Tomoaki SAWADA, Osaka (JP)

(73) Assignee: PANASONIC INTELLECTUAL PROPERTY MANAGEMENT CO., LTD., Osaka (JP)

(21) Appl. No.: 19/239,069

(22) Filed: Jun. 16, 2025

Related U.S. Application Data
(63) Continuation of application No. PCT/JP2023/035102, filed on Sep. 27, 2023.

(30) Foreign Application Priority Data
Dec. 22, 2022 (JP) 2022-205236

(51) Int. Cl. H05K 3/00; B32B 7/12; B32B 27/08; B32B 27/38; B32B 27/40; B32B 33/00; B32B 38/00; H05K 1/02; H05K 1/03; H05K 1/09; H05K 3/46

(52) U.S. Cl. CPC H05K 3/0044; B32B 7/12; B32B 27/08; B32B 27/38; B32B 27/40; B32B 33/00; B32B 38/0012; H05K 1/0283; H05K 1/0298; H05K 1/0313; H05K 1/092; H05K 3/4635; B32B 2250/02; B32B 2250/24; B32B 2255/10; B32B 2255/205; B32B 2307/202; B32B 2307/51; B32B 2311/08; B32B 2363/00; B32B 2375/00; B32B 2457/08

(57) ABSTRACT

One aspect of the present invention relates a method for producing a laminate for an electronic device including laminating a resin film having a conductive layer (B) on at least one surface thereof on a surface of a base material having a conductive layer (A) with an adhesive layer interposed therebetween, and electrically connecting at least two conductive layers among the conductive layers by performing crimping on at least one of before and after the lamination.

### FIELD OF INVENTION

The present invention relates to a laminate for an electronic device, a method for producing the same, and an electronic device using the same.

### BACKGROUND ART

With advances in the electronics field, the demand for downsizing, thinning, weight saving, and densification of electronic devices and the like is further increasing. Furthermore, flexible devices that can be freely deformed and bent may be required in order to dispose the electronic devices on curved surfaces, uneven surfaces, and the like depending on the application. In recent years, a circuit board having elasticity has been proposed corresponding to this. For example, Patent Literature 1 describes a bendable and stretchable electronic device and a method for producing the same.

As a method for producing a stretchable electronic device that has been reported so far, as described in Patent Literature 1, a method for depositing a trace material on a stretchable base material (elastomer material), performing etching or the like, directly attaching a component (die or component) thereon, and sealing the component with an elastomer is generally used.

However, when a component is directly mounted on a stretchable base material, there may be a problem that the base material melts or deforms due to high temperature when reflow soldering is performed. Therefore, it is necessary to use a material having heat resistance as the base material, and there is a problem that selection of the stretchable base material can be limited. Further, when the base material is deformed, defective mounting of a component may occur.

The present invention is made in view of such circumstances, and an object of the present invention is to provide a method for producing a laminate for an electronic device, which can omit a step of reflow soldering, has no limitation on a substrate material, and can suppress defective mounting.
Patent Literature 1: JP 2016-527730 T

### SUMMARY OF THE INVENTION

As a result of intensive studies, the present inventors found that the problems can be solved by a laminate having the following configuration, and completed the present invention by conducting further studies based on this finding.

That is, a method for producing a laminate for an electronic device according to one aspect of the present invention includes laminating a resin film having a conductive layer (B) on at least one surface thereof on a surface of a base material having a conductive layer (A) with an adhesive layer interposed therebetween, and electrically connecting at least two conductive layers among the conductive layers by performing crimping on at least one of before and after the lamination.

### BRIEF DESCRIPTION OF THE DRAWINGS

FIGS. 1A and 1B are schematic cross-sectional views of a laminate obtained by a producing method according to an embodiment of the present invention.

FIGS. 2A to 2C are schematic views illustrating a process of a producing method according to an embodiment of the present invention. The upper part is a cross-sectional view, and the lower part is a top view.

FIG. 3 is a schematic cross-sectional view illustrating an example of conduction by crimping in the producing method according to the embodiment of the present invention.

FIGS. 4A to 4E are schematic cross-sectional views illustrating a laminate used in Examples 1 to 5.

FIGS. 5A to 5D are schematic cross-sectional views illustrating a laminate used in Examples 6 to 9.

FIGS. 6A and 6B are schematic views of an electronic device produced in Example 10, where FIG. 6A is a schematic cross-sectional view, and FIG. 6B is a schematic top view.

FIGS. 7A to 7D are schematic cross-sectional views illustrating a laminate used in Examples 11 to 14.

### DETAILED DESCRIPTION

A method for producing a laminate for an electronic device according to the present embodiment includes laminating a resin film having a conductive layer (B) on at least one surface thereof on a surface of a base material having a conductive layer (A) with an adhesive layer interposed therebetween, and electrically connecting at least two conductive layers among the conductive layers by performing crimping on at least one of before and after the lamination.

With such a configuration, when an electronic device is produced using a substrate, a step of reflow soldering can be omitted, a substrate material to be used (particularly, a stretchable material) is also less limited, and a range of usable materials is widened. In addition, since the reflow step can be omitted, it is possible to produce a laminate for an electronic device in which defective mounting is suppressed.

In a case where the laminate for a stretchable electronic device is produced by the producing method of the present embodiment, the stretchable portion and the mounting portion can be processed separately, and complicated circuit mounting and the like can be performed in the same step as the conventional flexible printed wiring board. In addition, even when the component mounted portion and the conductive layer on the base material are insulated from each other with an adhesive layer interposed therebetween, the component mounted portion and the conductive layer can be directly joined and electrically connected by crimping. Further, since the interlayer conduction step by via processing or plating of the portion of the mounting substrate can also be substituted by crimping, the via processing performed so far can be omitted. In addition, since wiring bonding between the substrate and the stretchable base material can also be performed by crimping, there is also an advantage that a connector that has been used so far is not required.

Therefore, according to the producing method of the present embodiment, it is considered that a highly reliable electronic device can be efficiently and easily produced.

Hereinafter, specific embodiments of the present invention will be described with reference to the drawings and the like. The embodiment described below is only one of various embodiments of the present invention. The following embodiment can be modified in various ways depending on the design as long as the object of the present invention can be achieved. In addition, reference numerals in the drawings indicate the following: 1 laminate for an electronic device, 1′ precursor, 2 base material, 3 conductive layer (A), 4 adhesive layer, 5 resin film, 6, 6′ conductive layer (B), 7 electronic component, 8 crimping, 9 solder.

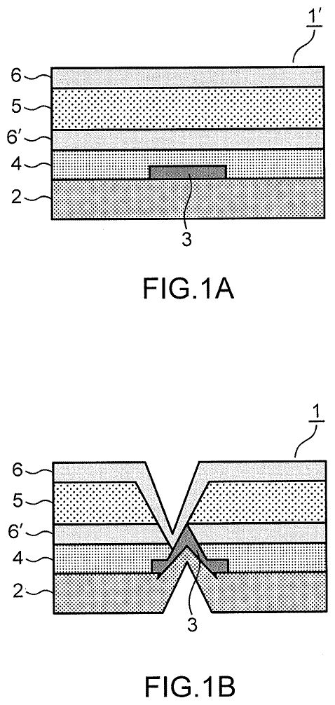

In the present embodiment, first, as illustrated in FIG. 1A, an adhesive layer 4 is provided on a surface of a base material 2 having a conductive layer (A) 3, and a resin film 5 having a conductive layer (B) on at least one surface thereof is laminated thereon to obtain a precursor 1′ of a laminate. In FIG. 1A, the resin film 5 includes the conductive layer (B) (the conductive layer (B) 6 on the front surface and the conductive layer (B) 6′ on the back surface) on both surfaces, but the resin film 5 may include the conductive layer (B) only on one of the surfaces. From the viewpoint of further exhibiting the effect of the present invention, it is preferable that the resin film 5 has the conductive layer (B) 6 on both surfaces, or in the case of one surface, the resin film 5 has the conductive layer (B) 6 at least on the base material 2 side.

Next, as illustrated in FIG. 1B, crimping is performed to electrically connect the conductive layer (A) 3, the conductive layer (B) 6, and the conductive layer (B) 6′, thereby obtaining the laminate for an electronic device 1. In FIG. 1, the base material 2, the adhesive layer 4, and the resin film 5 are laminated and then crimped. However, the present embodiment is not limited to this. For example, in a case where the resin film 5 includes the conductive layers (B) on both surfaces, the conductive layers (B) may be electrically connected to each other by crimping and then the resin film 5 may be laminated on the adhesive layer 4.

In the present embodiment, crimping means that pressure is applied so as to sandwich the precursor 1′ of the laminate from both the front and back directions, so that at least two conductive layers are penetrated and caulked, and both the conductive layers are brought into contact with each other to conduct electricity.

In FIG. 1B, crimping is performed by sandwiching the conductive layer (B) 6 and the conductive layer (B) 6′ of the resin film 5 on both surfaces and the conductive layer (A) 3, but the form of crimping is not limited thereto, and conduction can be achieved in various forms as described later.

Each step in the producing method of the present embodiment will be described more specifically.

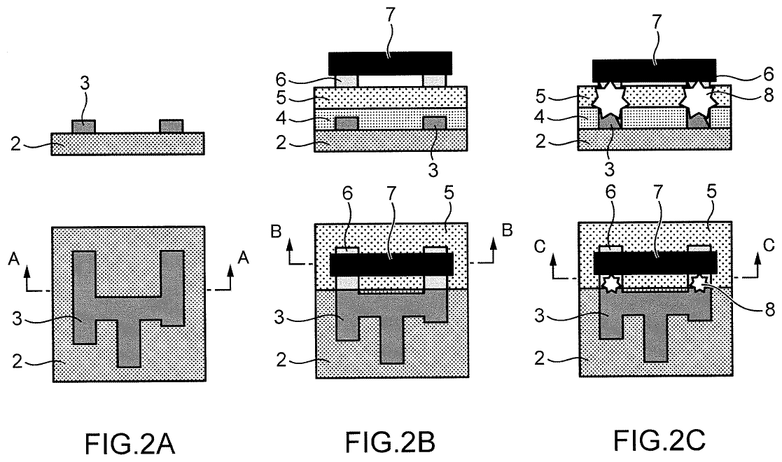

FIG. 2 is a view illustrating an example of each process of the producing method of the present embodiment, and an upper part is a cross-sectional view and a lower part is a top view. Each of the cross-sectional views in the upper part is a cross-sectional view taken along a line in the top view in the lower part.

### (Formation of Base Material and Conductive Layer (A))

First, as illustrated in FIG. 2A, a conductive layer (A) 3 is provided on the base material 2.

The base material used in the present embodiment is not particularly limited as long as it is a base material used for a substrate of an electronic device, but is preferably a stretchable base material having stretchability. The stretchable base material makes it possible to produce a device having shape followability. That is, when lamination is performed in a state where there is a wiring pattern on the base material 2, that is, in a state where there is unevenness on the surface, it is easy to follow the unevenness, and the thickness of the adhesive layer can be reduced, so that the accuracy and reliability of crimping are improved. In addition, in a case where a base material having no stretchability is used, splits and cracks may occur around the crimping site during crimping. On the other hand, in a case where the stretchable base material is used, splits and cracks are hardly generated around the crimping site during crimping, and it is considered that the stretchable base material has high reliability.

Examples of the stretchable base material include base materials such as polyimide, polyetherimide, polyethylene terephthalate, polybutylene terephthalate, polyethylene naphthalate, polyethylene, polypropylene, polycarbonate, polyvinyl chloride, polyvinylidene chloride, polyvinyl alcohol, vinylon, cellulose, cellulose acetate, polyolefin, polystyrene, polyacrylate, triacetate, nylon, aramid, polyethersulfone, polyphenylsulfide, polyetheretherketone, polyacetal, norbornene resin, fluororesin, polymethylpentene resin, styrene-butadiene-acrylonitrile copolymer, ethylene-vinyl acetate copolymer, styrene-acrylonitrile copolymer, ethylene tetrafluoride-propylene hexafluoride copolymer, ethylene tetrafluoride-perfluoroalkoxyethylene copolymer, ethylene tetrafluoride copolymer, and vinylidene fluoride. The resin base material as described above may be laminated with fibers or the like.

In addition, “exhibiting stretchability” refers to being elastically deformable in the present specification, and the stretchable base materials of the present embodiment preferably satisfy the tensile modulus and/or percentage elongation after fracture described below. More specifically, the tensile modulus of the stretchable base material is preferably 0.1 MPa or more. The upper limit is not particularly limited, but is preferably 100 MPa or less. The tensile modulus is more preferably 1.0 MPa or more and 50 MPa or less, still more preferably 1.5 MPa or more and 30 MPa or less.

The percentage elongation after fracture of the stretchable base material according to the present embodiment is preferably 50% or more. In the present embodiment, the percentage elongation after fracture refers to the elongation rate until fracture, and is an index indicating the flexibility of the stretchable base material together with the above-described tensile modulus. A more preferable percentage elongation after fracture is 100% or more and 500% or less. It is preferable as the upper limit of the percentage elongation after fracture in the present embodiment is as high as possible, but 1000% is sufficient.

An electronic device including a stretchable base material having a tensile modulus and/or a percentage elongation after fracture within ranges as described above exhibits high followability when deformed into an arbitrary shape, and it is thus considered that, for example, an electronic device such as a circuit board that exhibits excellent followability to clothing, is less likely to be fractured, and exhibits excellent stretchability can be obtained.

The tensile modulus and percentage elongation after fracture of the present embodiment are values measured by the following methods.

First, the tensile modulus is measured as follows. The cured product of a resin constituting the stretchable base material is cut into a size of 50 mm×5.5 mm and attached to a universal testing machine (AGS-X produced by Shimadzu Corporation). Then, the test is conducted at room temperature (25° C.) and a tension speed of 500 mm/min, and the slope of r-σ (initial tensile modulus) is determined from all the stress (σ) data corresponding to the strain (r) at 1.0% to 5.0% elongation by the least squares method to calculate the tensile modulus.

$$Strain ( r ) = x / x 0 ( x is gripper moving distance , x 0 is intital distance between grippers )$$

$$Stress ( σ ) = F / ( d \cdot 1 ) ( F is test force , d is film thickness , and 1 is width of test piece )$$

Regarding the percentage elongation after fracture, the percentage elongation when cured product is fractured is measured using the testing machine.

The tensile stress of the stretchable base material according to the present embodiment at 50% elongation is preferably 0.1 MPa or more and 20 MPa or less. “Tensile stress at 50% elongation” refers to the tensile stress when the percentage elongation reaches 50% in the above-described tensile test, and is an index indicating the flexibility of the stretchable base material together with the above-described tensile modulus. As the tensile stress at 50% elongation is within the above range, the stretchable base material exhibits high followability when deformed into an arbitrary shape (similarly to the tensile modulus described above), and there is an advantage that wirings and component mounted portions are less likely to be fractured. A more preferable range of the tensile stress is 0.5 MPa or more and 15 MPa or less.

The stretchable base material of the present embodiment is preferably formed of a curable resin composition or a thermoplastic resin composition. Examples of the resin containing the curable resin composition or the thermoplastic resin composition include thermoplastic resins and thermosetting resins. Examples of the thermoplastic resin include urethane resins, various kinds of rubber, acrylic resins, olefin-based resins, ethylene propylene diene rubber, isoprene rubber, butadiene rubber, and chloroprene rubber. In the present embodiment, it is particularly preferable to use a curable resin composition containing a thermosetting resin from the viewpoint of excellent adhesiveness and heat resistance, and from the viewpoint of being able to impart functions such as chemical resistance. As the thermosetting resin, it is preferable to use at least one selected from epoxy resins, urethane resins, silicone resins, polyrotaxane resins, isocyanate resins, polyol resins, hydrogenated styrene-based elastomer resins, and acrylic acid ester copolymer resins. Among them, it is more preferable to use epoxy resins and urethane resins.

Furthermore, the resin composition may contain various additives such as a curing agent, a curing accelerator, a filler, an antioxidant, a leveling agent, a pigment, and a dye agent as long as the effects of the present invention are not impaired.

The conductive layer (A) 3 provided on the base material 2 may be provided on at least a part of the base material 2, but may be provided on the entire surface of the base material 2. The conductive layer (A) may be stretchable or non-stretchable regardless of whether the base material 2 is a stretchable base material, but is preferably composed of a conductive material containing at least one selected from a conductive resin composition or a metal. In addition, in the laminate for an electronic device exemplified in FIGS. 1 to 3, the resin layer (A) 3 is formed only on one surface (front surface) of the base material 2, but the present invention is not limited thereto, and the resin layer (A) 3 may be formed on the back surface of the base material, or may be provided on both the front surface and the back surface.

In the present embodiment, examples of the stretchable conductive material include a conductive resin composition (conductive paste). Examples of the conductive resin composition that can be used in the present embodiment include a conductive resin composition containing a binder resin composed of a thermosetting resin and/or a thermoplastic resin and conductive particles. Examples of the thermosetting resin include a silicone resin, a urethane resin, an epoxy resin, an acrylic resin, and a fluororubber, and examples of the thermoplastic resin include a urethane resin, an acrylic resin, an olefin-based resin, an ethylene propylene diene rubber, an isoprene rubber, a butadiene rubber, a chloroprene rubber, a nitrile rubber, and a polyester resin. In particular, from the viewpoint of adhesion to the adhesive layer and the conductive layer, it is preferable to use a urethane resin, an epoxy resin, an acrylic resin, an olefin-based resin, an ethylene propylene diene rubber, an isoprene rubber, a butadiene rubber, a chloroprene rubber, a nitrile rubber, or a polyester resin, and it is more preferable to use an acrylic resin, an epoxy resin, a urethane resin, a polyester resin, or a nitrile rubber.

Specific examples of the conductive particles include particles composed of silver, silver-coated copper (including a configuration in which a part of the surface of copper is coated with silver), copper, gold, carbon particles, carbon nanotubes, a conductive polymer, tin, bismuth, indium, gallium, nickel, aluminum, or an alloy of these metals.

In a preferred embodiment, for example, stretchable epoxy resins, acrylic resins, urethane resins, silicone resins, fluororesins, styrene-butadiene copolymer resins, polyester resins, and silver pastes and silver inks obtained by combining various rubbers with silver powder, silver flakes, and the like, copper pastes, copper inks, and the like can be used as conductive resin compositions.

Examples of the non-stretchable conductive material include metals, and more specific examples thereof include copper (including a surface treatment with gold or the like), aluminum, and nickel. In a case where the conductive layer made of metal is provided, the base material 2 may be bonded to a copper foil, an aluminum foil, a nickel foil, or the like using an adhesive, or the conductive layer (A) made of metal may be formed on the surface of the base material 2 by electroless plating, electrolytic plating, vapor deposition, or the like.

Alternatively, the conductive layer (A) may be made of a sintered body of metal particles, a liquid metal, or the like. The sintered body is obtained by heating fine particles of silver, copper, gold, or the like at an appropriate firing temperature to melt the particles or the surfaces of the particles to dissolve the particles or the surfaces of the particles in a solid solution, and is obtained by printing, heating, drying, and firing a metal particle-dispersed ink in which the fine particles are dispersed in water or an organic solvent. Examples of the liquid metal that can be used in the present embodiment include gallium simple substance or gallium/indium alloy, gallium/indium/tin alloy, and gallium/indium/tin/zinc alloy.

The thicknesses of the base material and the conductive layer (A) of the present embodiment are not particularly limited, but the base material is usually 10 μm or more and 1000 μm or less, and the conductive layer (A) is usually about 0.01 μm or more and 50 μm or less. Thereby, there is an advantage that conduction reliability by crimping can be more reliably obtained. The thickness of the base material is more preferably about 30 μm or more and 200 μm or less, and the thickness of the conductive layer (A) is about 1 μm or more and 35 μm or less.

The conductive layer (A) may be a circuit formed in a pattern as illustrated in FIG. 2A. The method for forming the circuit is also not particularly limited, and for example, the circuit (wiring) can be formed by performing etching processing or the like on the conductive layer (A) formed of a metal foil provided on the base material 2. Examples of the circuit forming method include circuit formation by a semi additive process (SAP) or a modified semi additive process (MSAP) in addition to the method described above.

Alternatively, a method for forming a circuit using a conductive composition or the like can be performed by, for example, a printing method or the like. Specifically, in a case where the conductive layer (A) is composed of a paste or liquid metal of a conductive resin composition, a circuit having a desired pattern can be formed by printing and applying the conductive layer (A) on the base material 2 by a printing method such as screen printing, inkjet printing, gravure printing, or offset printing.

In a case where the conductive layer (A) is composed of a sintered body of metal particles, for example, a circuit pattern can be formed on the base material 2 by printing an ink (metal particle-dispersed ink) containing the sintered body of metal particles as described above by inkjet or the like, followed by heating, drying, and firing.

In addition to the above, examples of a method for forming the circuit pattern as the conductive layer (A) include a method for forming the circuit pattern by electrolysis or electroless plating, and a method for forming the circuit pattern by depositing a metal.

The conductive layer (A) is provided on at least one surface or both surfaces of the resin film. In a case where the conductive layer (A) is provided on one surface, the conductive layer (A) is preferably provided on the adhesive layer side. Even when the conductive layer (A) is provided on both surfaces or one surface of the resin film, it is considered that more reliable conduction can be obtained in a case where the conductive layer (A) is provided on the adhesive layer side.

### (Formation of Adhesive Layer)

Next, the adhesive layer 4 is provided on the base material 2 provided with the conductive layer (A) 6. The adhesive layer 4 is provided on the surface of the base material 2 on which the conductive layer (A) is provided or on the opposite surface thereof, and is a layer for bonding the base material 2 and a resin film 5 described later. As the adhesive layer 4, an adhesive, a pressure-sensitive adhesive, or the like used in the field of electronic devices can be used without particular limitation.

Examples of the adhesive that can be used in the present embodiment include thermoplastic adhesives and thermosetting adhesives. More specifically, the thermoplastic adhesive is, for example, an adhesive containing polyvinyl alcohol, an acrylic resin, polyvinyl acetate, polyethylene, polyolefin, polyamide, polyester, various rubbers, or polyurethane as a main component. As the thermosetting adhesive, for example, an epoxy resin-based adhesive, a phenol resin-based adhesive, or the like can be used. The thermosetting adhesive may be composed of a semi-cured product of a resin or the like.

Examples of the pressure-sensitive adhesive include rubber-based pressure-sensitive adhesives, acryl-based pressure-sensitive adhesives, silicone-based pressure-sensitive adhesives, and urethane-based pressure-sensitive adhesives. From the viewpoint of adhesion, an acryl-based pressure-sensitive adhesive or a urethane-based pressure-sensitive adhesive is preferable.

Further, the adhesive layer of the present embodiment may contain a conductive material. In that case, conduction between the conductive material of the adhesive layer and the conductive layer (A) and/or the conductive layer (B) can also be obtained by crimping.

The method for forming the adhesive layer 4 is not particularly limited, and for example, in a case where an adhesive or the like is used, the adhesive layer 4 can be formed by applying the adhesive to a desired thickness on the base material 2, or by bonding a film-shaped adhesive film, an adhesive film, or the like.

The thickness of the adhesive layer 4 is not particularly limited, but is usually about 5 μm or more and 500 μm or less from the viewpoint of maintaining adhesive strength and efficiently obtaining conduction by crimping. In order for more efficient conduction by crimping, the thickness is more preferably about 5 μm or more and 100 μm or less, still more preferably 5 μm or more and 50 μm or less.

Further, the adhesive layer 4 may have a metal layer on the surface (one surface or both surfaces) or inside. Thereby, there is an advantage that the conduction reliability of crimping with the conductive layer (A) is improved.

As such an adhesive layer, for example, the adhesive layer 4 having a metal layer can be obtained by using an adhesive film having a metal foil supporting base material or providing a metal layer made of a metal foil as an intermediate layer of an adhesive layer formed of an adhesive.

### (Resin Film Having Conductive Layer (B))

Next, as illustrated in FIG. 2B, the resin film 5 having the conductive layer (B) 6 is laminated on the base material 2 with the adhesive layer 4 interposed therebetween.

The conductive layer (B) is provided on at least one surface, preferably both surfaces, of the resin film. In a case where the conductive layer (B) is provided on one surface, the conductive layer (B) is preferably provided on the adhesive layer side. Even when the conductive layer (B) is provided on both surfaces or one surface of the resin film, it is considered that more reliable conduction can be obtained in a case where the conductive layer (B) is provided on the adhesive layer side. As the resin film including such a conductive layer (B), a general metal foil with resin used in technical fields such as electronic devices and wiring boards can be used without particular limitation.

Specifically, for example, a resin film 5 made of a resin composition or a semi-cured product of the resin composition and a conductive layer (B) 6 made of a metal foil or the like are laminated. The resin contained in the resin film is not particularly limited, and may be a thermosetting resin or a thermoplastic resin. From the viewpoint of heat resistance, chemical resistance, prevention of slack due to stretching, and the like, a resin film containing a thermosetting resin is preferable. In a preferred embodiment, examples of the thermosetting resin include an epoxy resin, an acrylic resin, a urethane resin, and various rubbers.

The resin film 5 may be a film composed of the cured resin composition (C-stage), or may be a film composed of a semi-cured product (B-stage) of the resin composition, but it is more preferably a cured resin composition (C-stage) from the viewpoint of stickiness and workability of crimping.

As the conductive layer (B), metal foils generally used in metal-clad laminates, wiring boards, and the like can be used without limitation, and examples thereof include a copper foil and an aluminum foil.

The thicknesses of the resin film 5 and the conductive layer (B) are not particularly limited, but the resin film is usually 10 μm or more and 1000 μm or less, and the conductive layer (B) is usually about 0.01 μm or more and 100 μm or less. Thereby, there is an advantage that conduction reliability by crimping can be more reliably obtained. Preferably, the resin film has a thickness of 20 μm or more and 200 μm or less, and the conductive layer (B) has a thickness of about 1 μm or more and 35 μm or less.

The conductive layer (B) may be a circuit formed in a pattern as illustrated in FIG. 2B. The method for forming the circuit is also not particularly limited, and for example, the circuit (wiring) can be formed by performing etching processing or the like on the conductive layer (B) formed of a metal foil. Other examples of the circuit forming method include circuit formation by a semi additive process (SAP) or a modified semi additive process (MSAP).

### (Crimping)

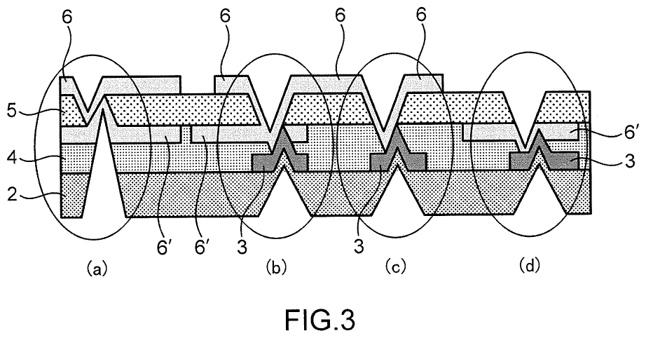

Next, as illustrated in FIG. 2C, a conductive layer to be electrically connected in the laminate is selected, and the crimping 8 is performed thereon to electrically connect the conductive layer, thereby obtaining a laminate for an electronic device. In the producing method of the present embodiment, as illustrated in FIG. 3, it is possible to obtain a laminate having various conduction patterns by crimping.

That is, in the present embodiment, at a position where the conductive layer and the conductive layer to be conductive exist, crimping is performed to bring both the conductive layers into contact with each other to conduct electricity. For example, in FIG. 2C, the conductive layer (A) 6 provided on the base material 2 and the conductive layer (B) provided on the surface of the resin film 5 are electrically connected by the crimping 8.

FIG. 3 shows some specific examples of the conduction pattern. For example, in the embodiment illustrated in (a) of FIG. 3, a case where the resin film 5 has the conductive layer (B1) 6 on the front surface and the conductive layer (B2) 6′ on the back surface is shown, and the conductive layer (B1) 6 and the conductive layer (B2) 6′ are electrically connected. That is, in this embodiment, crimping is performed at a portion of the base material 2 where the conductive layer (A) is not provided, and the two conductive layers (B1) 6 and (B2) 6′ of the resin film are electrically connected.

Further, in a case where the resin film 5 has the conductive layer (B1) on the front surface and the conductive layer (B2) on the back surface, it is also possible to electrically connect the conductive layer (A) and the conductive layer (B1), to electrically connect the conductive layer (A) and the conductive layer (B2), and to electrically connect the conductive layer (A) 3, the conductive layer (B1) 6, and the conductive layer (B2) 6′ as illustrated in (b) of FIG. 3.

In the embodiment illustrated in (c) and (d) of FIG. 3, the resin film 5 includes the conductive layer (B) 6 on either the front surface or the back surface. That is, in (c) of FIG. 3, the conductive layer (B) 6 provided on the front surface of the resin film 5 and the conductive layer (A) 3 of the base material 2 are electrically connected, and in (d) of FIG. 3, the conductive layer (B) 6 provided on the back surface of the resin film 5 and the conductive layer (A) 3 of the base material 2 are electrically connected.

Alternatively, although not illustrated, even in a case where the resin film 5 has the conductive layer (B1) 6 on the front surface and the conductive layer (B2) 6′ on the back surface, it is also possible to electrically connect the conductive layer (A) and only the conductive layer (B1) and to electrically connect the conductive layer (A) and only the conductive layer (B2) by adjusting the position where crimping is performed. Although not illustrated, it is also possible to provide a conductive layer on the back surface of the base material 2 and electrically connect the conductive layer and the conductive layer (A) 3 on the front surface of the base material 2, the conductive layer (B1) 6 on the front surface of the resin film 5, the conductive layer (B2) 6′ on the back surface of the resin film 5, and the like by crimping.

As described above, in the present embodiment, crimping can be performed at various desired locations of the laminate, and the conductive layer to be electrically connected can be freely and easily selected. In any of the examples described above, crimping is performed after the base material and the resin film are laminated, but the present invention is not limited to such an embodiment, and it is also possible to crimp the base material film before lamination and then laminate the base material and the film. Furthermore, although not illustrated, the number of stacked layers can be increased.

In addition, by electrically connecting the conductive layers by crimping, the conventional solder reflow step can be omitted. Thereby, options in the material of the base material (particularly, the stretchable base material) are widened, and the occurrence of defective mounting can also be suppressed. In addition, the interlayer conduction step by via processing or plating, which has been performed in the production of the conventional wiring board, and the wiring bonding between the substrate and the stretching base material can also be omitted by crimping. Further, even if there is an adhesive layer which is insulated between the conductive layers to be electrically connected, the conductive layers can be electrically connected by crimping.

The laminate for electronic devices obtained by the above steps can be used as a material or a substrate for various electronic components in various applications. In particular, since it is excellent in flexibility and mounting reliability, it is very suitable as a material used for electronic devices such as bendable electronic paper, organic EL displays, wearable devices, sensors, and antennas.

### (Method for Producing Electronic Device)

The method for producing an electronic device according to the present embodiment further includes mounting an electronic component on the laminate obtained as described above.

The electronic component that can be mounted in the present embodiment is not particularly limited, and examples thereof include wireless modules such as resistances, transistors, signal transmission elements, light emitting elements, solar power generation elements, diodes, switching elements, capacitors, coils, liquid crystals, and Bluetooth (registered trademark), various sensors such as acceleration sensors, humidity sensors, and temperature sensors, chip parts to be used for RFIDs and the like.

The timing of mounting the electronic component is not particularly limited, and the electronic component 7 may be mounted on the conductive layer (B) 6 before crimping as illustrated in (b) of FIG. 3 after the laminate for an electronic device is obtained by the producing method described above. In the present embodiment, even in the laminate on which the electronic component 7 is mounted, it is possible to finely select the position where the crimping is performed, so that the conductive layer (A) 3 and the conductive layer (B) 6 can be electrically connected as illustrated in the lower part in (c) of FIG. 3. From the viewpoint of heat resistance in the base material 2, it is more preferable to perform mounting before laminating the resin film 5.

The electronic component can be mounted by, for example, a mounting method using a conductive pressure-sensitive adhesive or an adhesive or a mounting method using solder and reflow. In addition, it is also possible to print and form an element on a base material instead of solder mounting.

This specification discloses techniques in various aspects as described above, and the main techniques among them are summarized below.

A method for producing a laminate for an electronic device according to a first aspect of the present invention includes laminating a resin film having a conductive layer (B) on at least one surface thereof on a surface of a base material having a conductive layer (A) with an adhesive layer interposed therebetween, and electrically connecting at least two conductive layers among the conductive layers by performing crimping on at least one of before and after the lamination.

A producing method according to a second aspect is the producing method according to the first aspect, the producing method including laminating a resin film having a conductive layer (B) on at least one surface thereof on a surface of a base material having the conductive layer (A) with an adhesive layer interposed therebetween, and then at least two conductive layers of the conductive layers are electrically connected by performing crimping.

A producing method according to a third aspect is the producing method according to the first or second aspect, the producing method including electrically connecting the conductive layer (A) and the conductive layer (B) by performing crimping.

A producing method according to a fourth aspect is the producing method according to any one of the first to third aspects, in which the resin film has a conductive layer (B1) on a front surface and a conductive layer (B2) on a back surface.

A producing method according to a fifth aspect is the producing method according to the fourth aspect, the producing method including electrically connecting the conductive layer (A) to the conductive layer (B1) or the conductive layer (B2) by performing crimping.

A producing method according to a sixth aspect is the producing method according to the fourth aspect, the producing method including electrically connecting the conductive layer (A) to the conductive layer (B1) and the conductive layer (B2) by performing crimping.

A producing method according to a seventh aspect is the producing method according to the fourth aspect, the producing method including electrically connecting the conductive layer (B1) and the conductive layer (B2) by performing crimping.

A producing method according to an eighth aspect is the producing method according to any one of the first to seventh aspects, in which the base material of the conductive layer (A) is a stretchable base material.

A producing method according to a ninth aspect is the producing method according to any one of the first to eighth aspects, in which the conductive layer (A) is made of a conductive material containing at least one selected from a conductive resin composition and a metal.

A producing method according to a tenth aspect is the producing method according to any one of the first to ninth aspects, in which the adhesive layer includes a metal layer.

A method for producing an electronic device according to an eleventh aspect includes mounting an electronic component on a laminate for an electronic device obtained by the producing method according to any one of the first to tenth aspects.

A laminate for an electronic device according to a twelfth aspect includes a resin film which has a conductive layer (B) on at least one surface thereof and is laminated on a surface of a base material having a conductive layer (A) with an adhesive layer interposed therebetween, in which at least two conductive layers of the conductive layers are electrically connected by crimping.

An electronic device according to a thirteenth aspect includes: the laminate for an electronic device according to the twelfth aspect; and an electronic component.

Hereinafter, the present invention will be described more specifically with reference to Examples, but the scope of the present invention is not limited thereto.

### EXAMPLE

First, all kinds of materials used in the present Examples are as follows.

### <Stretchable Base Material>

Cured product of thermosetting stretchable film (thickness: 100 μm):

### Production Example 1

In a solvent (MEK/toluene (mass ratio: 4/6)), 100 parts by mass of polyrotaxane “SH3400P” (produced by Advanced Softmaterials Inc.), 90 parts by mass of an epoxy resin “JER1003” (produced by Mitsubishi Chemical Corporation), 2 parts by mass of monofunctional acid anhydride “YH-307” (produced by Mitsubishi Chemical Corporation), and 1 part by mass of an imidazole-based curing accelerator “2E4MZ” (produced by Shikoku Chemicals Corporation) were dissolved with stirring to adjust a resin varnish having a concentration of 50 mass %. After being left to stand and defoamed, the resin varnish was applied to a release-treated PET film (SP-PETO1, produced by Mitsui Chemicals Tohcello, Inc.) using a bar coater. Then, the film was dried in an oven at 80° C. for 10 minutes to obtain a dried film A composed of a dried product of the resin composition. The dried film A was heated in an oven at 80° C. for 24 hours and heated at 160° C. for 1 hour to obtain a thermosetting stretchable film (thickness: 100 μm) composed of a cured product of a resin composition.
Cured product of thermosetting stretchable film with single-sided copper foil (thickness: 100 μm):

### Production Example 2

A thermosetting stretchable film (thickness: 100 μm) having a conductive layer made of a copper foil on one surface was obtained in the same manner as in Production Example 1 except that the release-treated PET film (SP-PET O1, produced by Mitsui Chemicals Tohcello, Inc.) was changed to a copper foil (CF-T9DA-SV, produced by Fukuda Metal Foil & Powder Co., Ltd.) having a thickness of 12 μm.
Thermoplastic polyurethane film “Silklon ES85” (produced by Okura Kogyo Co., Ltd., thickness: 100 μm)

### <Conductive Layer (A)>

Silver paste “LS-453-6B” (produced by Asahi Chemical Laboratory Co., Ltd.)
Copper foil “CF-T9DA-SV” (product name) (produced by Fukuda Metal Foil & Powder Co., Ltd., thickness: 12 μm)

### <Resin Film+Conductive Layer (B)>

Flexible substrate material 1: A resin (polyimide) film with single-sided copper foil, copper foil thickness: 12 μm, resin thickness: 100 μm) was prepared by removing the copper foil on one surface of the following flexible substrate material 2 by etching treatment.
Flexible substrate material 2 “FELIOS R-F775” (double-sided copper foil-attached resin (polyimide) film, copper foil thickness: 12 μm×2, resin thickness: 100 μm, produced by Panasonic Industry Co., Ltd.)
Flexible substrate material 3: A copper foil on one surface of “FELIOS R-F775” (double-sided copper foil-attached resin (polyimide) film, copper foil thickness: 12 μm×2, resin thickness: 25 μm, produced by Panasonic Industry Co., Ltd.) was removed by etching treatment.

### <Adhesive Layer>

Acryl-based adhesive “CS 6891” (produced by Nitto Denko Corporation)
Conductive adhesive film “Conductive Copper Foil Double-sided Tape No. 792” (Conductive double-sided tape having a copper foil supporting base material, produced by Teraoka Seisakusho Co., Ltd.)
Adhesive laminate having metal layer: Adhesive laminate in which copper foil is sandwiched between insulating adhesive layers; Laminate in which adhesive layers composed of 25 μm-thick acryl-based adhesive “CS 6891” (produced by Nitto Denko Corporation) are provided on both surfaces of copper foil “CF-T9DA-SV” (product name) (produced by Fukuda Metal Foil & Powder Co., Ltd., thickness: 12 μm)
Polyimide double-sided adhesive tape “Kapton (registered trademark) double-sided tape” (Kapton thickness: 25 μm, total thickness: 145 μm, produced by Teraoka Seisakusho Co., Ltd.)
Semi-cured product of thermosetting stretchable film:

### Production Example 3

The dried film A obtained in Production Example 1 was heated at 160° C. for 5 minutes to obtain a semi-cured film composed of a semi-cured product of a resin composition.

### Example 1

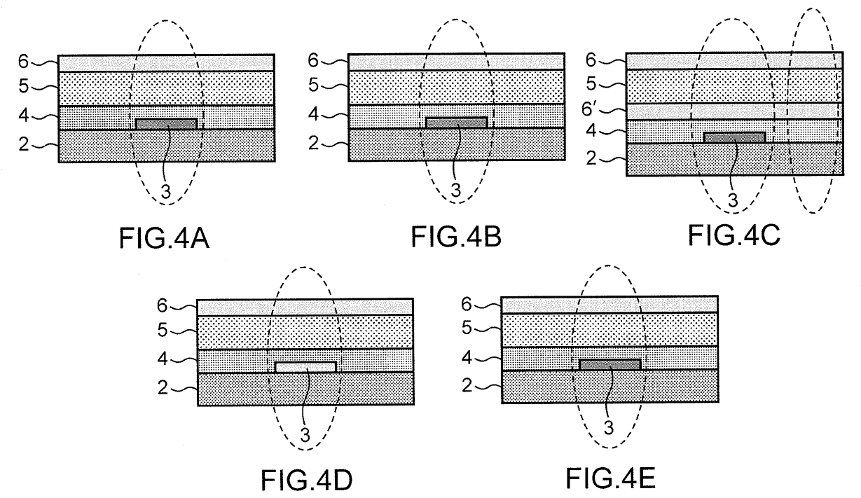

Using the thermosetting stretchable film obtained in Production Example 1 as a stretchable base material, a silver paste was printed thereon in a width of 5 mm and a length of 50 mm using a screen plate, and then cured by heating at 80° C. for 30 minutes to obtain a stretchable base material having a conductive layer (A) with a thickness of 15 μm. An acryl-based pressure-sensitive adhesive sheet (CS6891, thickness 25 μm, produced by Nitto Denko Corporation) was laminated on the surface of the obtained stretchable base material on the side provided with the conductive layer (A) to form an adhesive layer, and the flexible substrate material 1 (resin film having the conductive layer (B) on one surface) was bonded via the adhesive layer to obtain a precursor of a laminate illustrated in FIG. 4A.

Then, at the position where the conductive layer (A) was provided, pressure by crimping was applied from both the front and back surfaces of the laminate at the position indicated by the dotted line in FIG. 4A, and the conductive layer (A) 3 and the conductive layer (B) 6 were electrically connected to obtain a laminate of Example 1.

### Example 2

A precursor of a laminate (FIG. 4B) was obtained in the same manner as in Example 1 except that a thermoplastic polyurethane film was used as the stretchable base material, and pressure by crimping was applied from both the front and back surfaces of the laminate at a position indicated by a dotted line in FIG. 4B to electrically connect the conductive layer (A) 3 and the conductive layer (B) 6, thereby obtaining a laminate of Example 2.

### Example 3

A precursor of a laminate (FIG. 4C) was obtained in the same manner as in Example 1 except that the flexible substrate material 2 (resin film having conductive layers (conductive layer (B1) and conductive layer (B2)) on both surfaces) was used instead of the flexible substrate material 1. Thereafter, the conductive layer (A), the conductive layer (B1), and the conductive layer (B2) are electrically connected, and the conductive layer (B1) and the conductive layer (B2) are electrically connected by performing crimping at two positions indicated by dotted lines in FIG. 4C, thereby obtaining a laminate of Example 3.

### Example 4

A precursor of a laminate (FIG. 4D) was obtained in the same manner as in Example 1, except that the thermosetting stretchable film with single-sided copper foil obtained in Production Example 2 was used as a conductive layer (A), and the copper foil was developed by photolithography and etched to form the conductive layer (A) having a width of 5 mm and a length of 50 mm, and the conductive layer (A) 3 and the conductive layer (B) 6 were electrically connected by performing crimping at a position indicated by a dotted line in FIG. 4D, thereby obtaining a laminate of Example 4.

### Example 5

A precursor of a laminate (FIG. 4E) was obtained in the same manner as in Example 1 except that the flexible substrate material 3 (thin resin film having a conductive layer (conductive layer (B)) on one surface) was used instead of the flexible substrate material 1. In Example 5, the conductive layer (A) and the conductive layer (B) were electrically connected by performing crimping at a position indicated by a dotted line in FIG. 4E, and a laminate of Example 5 was obtained.

### Example 6

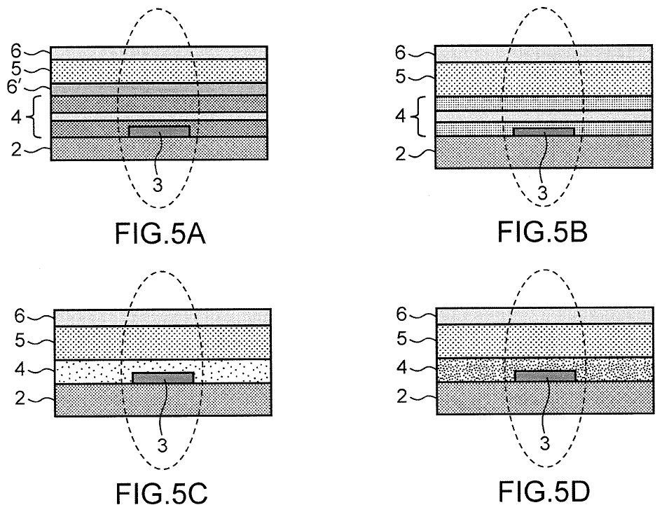

A precursor of a laminate (FIG. 5A) was obtained in the same manner as in Example 1 except that a conductive adhesive film was used as an adhesive layer, and the conductive layer (A), the adhesive layer, and the conductive layer (B) were electrically connected by performing crimping at a position indicated by a dotted line in FIG. 5A, thereby obtaining a laminate of Example 6.

### Example 7

A precursor of a laminate (FIG. 5B) was obtained in the same manner as in Example 1 except that an adhesive laminate with both sides of a metal layer sandwiched therebetween was used as the adhesive layer, and the conductive layer (A), the metal layer of the adhesive layer, and the conductive layer (B) were electrically connected by performing crimping at a position indicated by a dotted line in FIG. 5B, thereby obtaining a laminate of Example 7.

### Example 8

A precursor of a laminate (FIG. 5C) was obtained in the same manner as in Example 1 except that a polyimide double-sided adhesive tape was used as an adhesive layer, and the conductive layer (A) 3 and the conductive layer (B) 6 were electrically connected by performing crimping at a position indicated by a dotted line in FIG. 5C, thereby obtaining a laminate of Example 8.

### Example 9

Using the thermosetting stretchable film obtained in Production Example 1 as a stretchable base material, a silver paste was printed thereon in a width of 5 mm and a length of 50 mm using a screen plate, and then cured by heating at 150° C. for 10 minutes to obtain a stretchable base material having a conductive layer (A) with a thickness of 15 μm. The thermosetting stretchable semi-cured film obtained in Production Example 3 was laminated on the surface of the obtained stretchable base material on the side provided with the conductive layer (A) to obtain an adhesive layer. Thereafter, the flexible substrate material 1 (resin film having the conductive layer (B) on one surface) was laminated with the adhesive layer interposed therebetween, and heated at 160° C. for 60 minutes to cure the semi-cured product, thereby obtaining a precursor of a laminate as illustrated in FIG. 5D.

Then, pressure by crimping was applied from both the front and back surfaces of the laminate at a position where the conductive layer (A) was provided as indicated by a dotted line in FIG. 5D, and the conductive layer (A) 3 and the conductive layer (B) 6 were electrically connected to obtain a laminate of Example 9.

### Example 10

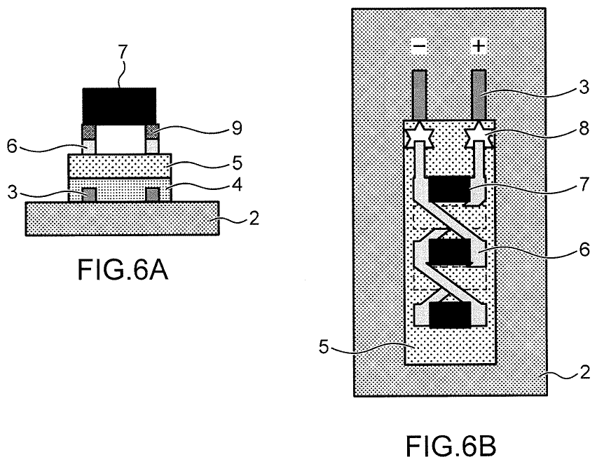

Using the thermosetting stretchable film obtained in Production Example 1 as a stretchable base material, two silver pastes each were printed thereon in a width of 5 mm and a length of 50 mm using a screen plate, and then cured by heating at 80° C. for 30 minutes to obtain a stretchable base material having a conductive layer (A) with a thickness of 15 μm. As illustrated in FIG. 6 (A: schematic cross-sectional view, B: schematic top view), the flexible substrate material 1 (resin film 5) having a width of 8 mm and mounted with three electronic components (LED) 7 and solder 9 was bonded to the surface of the obtained stretchable base material 2 on the side provided with the conductive layer (A) 3 via the adhesive layer 4 (acryl-based pressure-sensitive adhesive sheet (thickness: 25 μm)), and then the flexible substrate material 1 (resin film 5) was bonded on the two conductive layers (A) 3 so that the conductive layers (B) 6 of the positive electrode and the negative electrode were disposed, and crimping 8 was performed at a position where the components were not mounted, whereby the conductive layer (A) 3 and the conductive layer (B) 6 were electrically connected, and an electronic device of Example 10 was obtained. Note that a portion indicated by a dotted line in FIG. 6 indicates an insulating layer for preventing a short circuit of the cross wiring.

### Example 11

Using the thermosetting stretchable film obtained in Production Example 1 as a stretchable base material, a silver paste was printed thereon in a width of 5 mm and a length of 50 mm using a screen plate, and then cured by heating at 80° C. for 30 minutes to obtain a stretchable base material having a conductive layer (A) with a thickness of 15 μm. Then, a slightly adhesive film was bonded to the conductor layer surface, the release-treated PET film was peeled off, and the silver paste was printed in a width of 5 mm and a length of 50 mm using a screen plate, and then heated at 80° C. for 30 minutes to be cured, thereby obtaining a stretchable base material having a conductive layer (A) having a thickness of 15 μm on both surfaces.

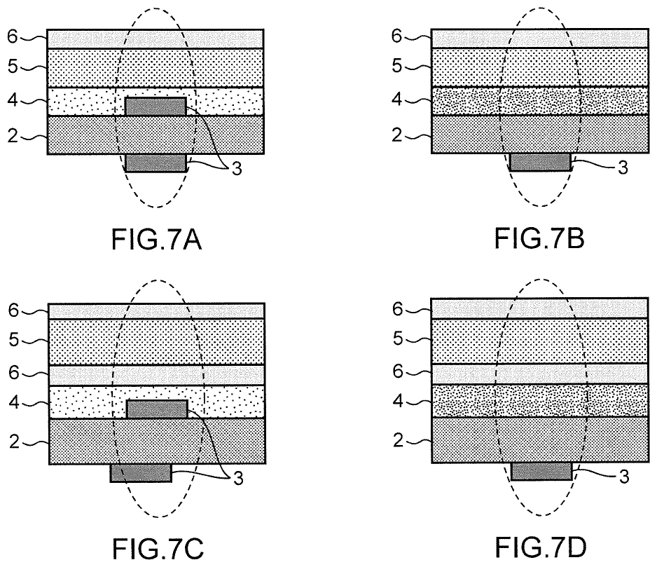

An acryl-based pressure-sensitive adhesive sheet (CS6891, thickness 25 μm, produced by Nitto Denko Corporation) was laminated on the surface of the obtained stretchable base material on the side provided with the conductive layer (A) to form an adhesive layer, and the flexible substrate material 1 (resin film having the conductive layer (B) on one surface) was bonded via the adhesive layer to obtain a precursor of a laminate illustrated in FIG. 7A. Then, the conductive layer (A) 3 and the conductive layer (B) 6 were electrically connected by performing crimping at a position indicated by a dotted line in FIG. 7A, thereby obtaining a laminate of Example 11.

### Example 12

A precursor of a laminate illustrated in FIG. 7B was obtained in the same manner as in Example 1 except that a side that was not a conductor layer surface was laminated in Example 1. Then, the conductive layer (A) 3 and the conductive layer (B) 6 were electrically connected by performing crimping was performed at a position indicated by a dotted line in FIG. 7B, thereby obtaining a laminate of Example 12.

### Example 13

Using the thermosetting stretchable film obtained in Production Example 1 as a stretchable base material, a silver paste was printed thereon in a width of 5 mm and a length of 50 mm using a screen plate, and then cured by heating at 80° C. for 30 minutes to obtain a stretchable base material having a conductive layer (A) with a thickness of 15 μm. Then, a slightly adhesive film was bonded to the conductor layer surface, the release-treated PET film was peeled off, and the silver paste was printed in a width of 5 mm and a length of 50 mm using a screen plate, and then heated at 80° C. for 30 minutes to be cured, thereby obtaining a stretchable base material having a conductive layer (A) having a thickness of 15 μm on both surfaces.

An acryl-based pressure-sensitive adhesive sheet (CS6891, thickness 25 μm, produced by Nitto Denko Corporation) was laminated on the surface of the obtained stretchable base material on the side provided with the conductive layer (A) to form an adhesive layer, and the flexible substrate material 2 (resin film having the conductive layer (B) on both surfaces) was bonded via the adhesive layer to obtain a precursor of a laminate illustrated in FIG. 7C. Then, the conductive layer (A) 3 and the conductive layer (B) 6 were electrically connected by performing crimping at a position indicated by a dotted line in FIG. 7C, thereby obtaining a laminate of Example 13.

### Example 14

A precursor of a laminate illustrated in FIG. 7D was obtained in the same manner as in Example 3 except that a side that was not a conductor layer surface was laminated in Example 3. Then, the conductive layer (A) 3 and the conductive layer (B) 6 were electrically connected by performing crimping at a position indicated by a dotted line in FIG. 7D, thereby obtaining a laminate of Example 14.

### [Evaluation Test]

A vibration test was performed under the following conditions.
Testing machine used: Composite vibration tester “EVS08-1010” (produced by ESPEC CORPORATION) Vibration mode: 5 to 200 Hz random excitation
Total excitation time: 108 min
   (Conduction after Vibration Test)

In Examples 1 to 9, the resistance value was confirmed by abutting a tester on the conductor layer (B) of the resin film and the conductor layer (A) of the stretchable base material before and after the vibration test. In Example 10, it was confirmed that the LED was lit before and after the vibration.

### (Change Rate in Resistance Value)

The change rate in the resistance value was calculated by the following equation, where R0 was before the vibration test and Rf was after the vibration test.

(Resistance value change rate %)=100×(Rf−R0)/R0

As the evaluation criteria, when the change rate was 100% or more, it was determined as “fair”, and when the change rate was less than 100%, it was determined as “good”.

The above results are summarized in Tables 1 to 3.

TABLE 1

| | Example 1 | Example 2 | Example 3 | Example 4 | Example 5 |
|---|---|---|---|---|---|
| Stretchable base | Stretchable | Polyurethane | Stretchable | Stretchable | Stretchable |
| material | film | film | film | film | film |
| Conductive layer (A) | Silver paste | Silver paste | Silver paste | Copper foil | Silver paste |
| Resin film + | Substrate 1 | Substrate 1 | Substrate 2 | Substrate 1 | Substrate 3 |
| Conductive layer (B) | | | | | |
| Adhesive layer | Acryl-based | Acryl-based | Acryl-based | Acryl-based | Acryl-based |
| | adhesive | adhesive | adhesive | adhesive | adhesive |
| Component mounting | — | — | — | — | — |
| Conduction after | OK | OK | OK | OK | OK |
| vibration test | | | | | |
| Resistance value | fair | fair | good | good | fair |
| change rate | | | | | |
| good<: +100% | | | | | |
| fair>: +100% | | | | | |

TABLE 2

| | Example 6 | Example 7 | Example 8 | Example 9 | Example 10 |
|---|---|---|---|---|---|
| Stretchable base | Stretchable | Stretchable | Stretchable | Stretchable | Stretchable |
| material | film | film | film | film | film |
| Conductive layer (A) | Silver paste | Silver paste | Silver paste | Silver paste | Silver paste |
| Resin film + | Substrate 1 | Substrate 1 | Substrate 1 | Substrate 1 | Substrate 1 |
| Conductive layer (B) | | | | | |
| Adhesive layer | Conductive | Adhesive | Polyimide | Semi-cured | Acryl-based |
| | adhesive | laminate | double-sided | product of | pressure- |
| | film | having | tape | stretchable | sensitive |
| | | metal layer | | film | adhesive |
| Component mounting | — | — | — | — | Yes LED |
| Conduction after | OK | OK | OK | OK | OK |
| vibration test | | | | | |
| Resistance value | good | good | fair | fair | fair |
| change rate | | | | | |
| good<: +100% | | | | | |
| fair>: +100% | | | | | |

TABLE 3

| | Example 11 | Example 12 | Example 13 | Example 14 |
|---|---|---|---|---|
| Stretchable base | Stretchable | Stretchable | Stretchable | Stretchable |
| material | film | film | film | film |
| Conductive layer (A) | Silver paste | Silver paste | Silver paste | Silver paste |
| | Both surfaces | One side back | Both surfaces | One side back |
| | | surface | | surface |
| Resin film + | Substrate 1 | Substrate 1 | Substrate 2 | Substrate 2 |
| Conductive layer (B) | | | | |
| Adhesive layer | Acryl-based | Acryl-based | Acryl-based | Acryl-based |
| | adhesive | adhesive | adhesive | adhesive |
| Component mounting | — | — | — | — |
| Conduction after | OK | OK | OK | OK |
| vibration test | | | | |
| Resistance value | good | fair | good | good |
| change rate | | | | |
| good<: +100% | | | | |
| fair>: +100% | | | | |

### DISCUSSION

As is apparent from the results in Tables 1 to 3, it was found that, according to the producing method of the present embodiment, conduction between the conductive layers can be obtained at various positions in the laminate for an electronic device, and the conduction is not lost even after the vibration test is performed. The same results were obtained also in Example 10 in which component mounting was performed.

In addition, in the laminate for an electronic device obtained by the producing method of the present embodiment, it was also confirmed that there is no large fluctuation in the resistance value before and after the vibration test. Furthermore, it was also found that, in a case where the resin film includes the conductive layer (B) on both surfaces, and in a case where the resin film includes the conductive layer (B) on the adhesive layer side, the variation in the resistance value is further suppressed.

This application is based on Japanese Patent Application No. 2022-205236 filed on Dec. 22, 2022, the contents of which are included in the present application.

In order to express the present invention, the present invention has been described above appropriately and sufficiently through the embodiments with reference to specific examples, drawings and the like. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

The present invention has a wide range of industrial applicability in the technical field relating to electronic devices.

1. A method for producing a laminate for an electronic device, comprising:
laminating a resin film having a conductive layer (B) on at least one surface thereof on a surface of a base material having a conductive layer (A) with an adhesive layer interposed therebetween; and
electrically connecting at least two conductive layers among the conductive layers by performing crimping on at least one of before and after the lamination.

2. The method for producing a laminate for an electronic device according to claim 1, comprising: laminating a resin film having a conductive layer (B) on at least one surface thereof on a surface of a base material having the conductive layer (A) with an adhesive layer interposed therebetween, and then electrically connecting at least two conductive layers of the conductive layers by performing crimping.

3. The method for producing a laminate for an electronic device according to claim 2, wherein the conductive layer (A) and the conductive layer (B) are electrically connected by performing crimping.

4. The method for producing a laminate for an electronic device according to claim 1, wherein the resin film has a conductive layer (B1) on a front surface and a conductive layer (B2) on a back surface.

5. The method for producing a laminate for an electronic device according to claim 4, wherein the conductive layer (A) is electrically connected to the conductive layer (B1) or the conductive layer (B2) by performing crimping.

6. The method for producing a laminate for an electronic device according to claim 4, wherein the conductive layer (A) is electrically connected to the conductive layer (B1) and the conductive layer (B2) by performing crimping.

7. The method for producing a laminate for an electronic device according to claim 4, wherein the conductive layer (B1) and the conductive layer (B2) are electrically connected by performing crimping.

8. The method for producing a laminate for an electronic device according to claim 1, wherein the base material having the conductive layer (A) is a stretchable base material.

9. The method for producing a laminate for an electronic device according to claim 1, wherein the conductive layer (A) is composed of a conductive material containing at least one selected from a conductive resin composition and a metal.

10. The method for producing a laminate for an electronic device according to claim 1, wherein the adhesive layer has a metal layer.

11. A method for producing an electronic device, comprising mounting an electronic component on the laminate for an electronic device obtained by the producing method according to claim 1.

12. The method for producing a laminate for an electronic device according to claim 8, wherein the stretchable base material contains at least one thermosetting resin selected from an epoxy resin, a urethane resin, and a polyrotaxane resin.

13. The method for producing a laminate for an electronic device according to claim 9, wherein the conductive layer (A) contains a silver paste.

14. The method for producing a laminate for an electronic device according to claim 1, wherein the resin film contains at least one thermosetting resin selected from an epoxy resin, an acrylic resin, a polyimide resin, and a urethane resin.

15. A laminate for an electronic device, comprising a resin film which has a conductive layer (B) on at least one surface thereof and is laminated on a surface of a base material having a conductive layer (A) with an adhesive layer interposed therebetween, wherein at least two conductive layers of the conductive layers are electrically connected by crimping.

16. An electronic device comprising:
the laminate for an electronic device according to claim 15; and
an electronic component.
